(19) United States
(12) Patent Application Publication
(10) Pub. No.: US 2005/0230725 A1
(43) Pub. Date: Oct. 20, 2005

(54) Ferroelectric capacitor having an oxide electrode template and a method of manufacture therefor

(75) Inventors: Sanjeev Aggarwal, Plano, TX (US); K.R. Udayakumar, Dallas, TX (US); Scott R. Summerfelt, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/828,446

(22) Filed: Apr. 20, 2004

(51) Int. Cl. H01L 21/00

(52) U.S. Cl. 257/295

(57) ABSTRACT

The present invention provides a ferroelectric capacitor, a method for manufacture therefor, and a ferroelectric random access memory (FeRAM) device. The ferroelectric capacitor (100), among other elements, may include a first electrode layer (162) located over a substrate (110), wherein the first electrode layer (162) includes iridium, and an oxide electrode template (164) located over the first electrode layer (162). The ferroelectric capacitor (100) may further include a ferroelectric dielectric layer (165) located over the oxide electrode template (164), and a second electrode layer (170) located over the ferroelectric dielectric layer (165).

### TECHNICAL FIELD OF THE INVENTION

The present invention is directed, in general, to a capacitor and, more specifically, to a ferroelectric capacitor having an oxide electrode template, a method of manufacture therefor, and an integrated circuit including the same.

### BACKGROUND OF THE INVENTION

Several trends exist, today, in the semiconductor device fabrication industry and the electronics industry. Devices are continuously getting smaller and smaller and requiring less and less power. A reason for this is that more personal devices are being fabricated which are very small and portable, thereby relying on a small battery as its only supply source. For example, cellular phones, personal computing devices, and personal sound systems are devices which are in great demand in the consumer market. In addition to being smaller and more portable, personal devices are requiring more computational power and on-chip memory. In light of all these trends, there is a need in the industry to provide a computational device which has memory and logic functions integrated onto the same semiconductor chip. Preferably, this memory will be configured such that if the battery dies, the contents of the memory will be retained. Such a memory device which retains its contents while power is not continuously applied to it is called a non-volatile memory. Examples of conventional non-volatile memory include: electrically erasable, programmable read only memory (“EEPPROM”) and FLASH EEPROM.

A ferroelectric memory (FeRAM) is a non-volatile memory which utilizes a ferroelectric material, such as strontium bismuth tantalate (SBT) or lead zirconate titanate (PZT), as a capacitor dielectric situated between a bottom electrode and a top electrode. Both read and write operations are performed for a FeRAM. The memory size and memory architecture affects the read and write access times of a FeRAM.

Currently, high temperatures (e.g., temperatures in excess of 550° C.) are required for the manufacture of the ferroelectric material of the FeRAM. These high temperatures are required to provide sufficient energy to adequately crystallize the ferroelectric material, especially when the ferroelectric material is formed on traditional lower metal electrodes having different lattice structures. As the desired crystallinity provides the requisite ferroelectric properties, high polarization and beneficial non-volativity required in todays FeRAM devices, it is quite important to achieve this desired crystallinity.

Unfortunately, the high temperatures required to adequately crystallize the ferroelectric material have deleterious effects on next generation devices. Specifically, the high temperatures required to adequately crystallize the ferroelectric material negatively affect the nickel silicides used in the next generation devices. Nevertheless, the use of nickel silicide is important to the acceptance of these next generation devices. Thus, there is a tradeoff between continuing to use cobalt silicide and keeping the temperatures high, and using nickel silicide and being required to substantially reduce the temperatures.

Accordingly, what is needed in the art is a ferroelectric capacitor, and method of manufacture therefore, that achieves the benefits of the high temperature ferroelectric material formation, as well as the use of nickel silicides, without experiencing the drawbacks associated with each.

### SUMMARY OF THE INVENTION

To address the above-discussed deficiencies of the prior art, the present invention provides a ferroelectric capacitor, a method for manufacture therefor, and a ferroelectric random access memory (FeRAM) device. The ferroelectric capacitor, among other elements, may include a first electrode layer located over a substrate, wherein the first electrode layer includes iridium, and an oxide electrode template located over the first electrode layer. The ferroelectric capacitor may further include a ferroelectric dielectric layer located over the oxide electrode template, and a second electrode layer located over the ferroelectric dielectric layer.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGURES. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

FIG. 1 illustrates a cross-sectional view of one embodiment of a ferroelectric random access memory (FeRAM) device constructed according to the principles of the present invention;

FIG. 2 illustrates a cross-sectional view of a partially completed FeRAM;

FIG. 3 illustrates a cross-sectional view of the partially completed FeRAM of FIG. 2 after forming a first electrode over the optional first protective layer;

FIG. 4 illustrates a cross-sectional view of the partially completed FeRAM of FIG. 3 after forming a ferroelectric dielectric layer 410 over the first electrode, and more particularly on the first oxide electrode template;

FIG. 5 illustrates a cross-sectional view of the partially completed FeRAM of FIG. 4 after forming a second electrode over the ferroelectric dielectric layer;

FIG. 6 illustrates a cross-sectional view of the partially completed FeRAM of FIG. 5 after forming a second protective layer over the second electrode;

FIG. 7 illustrates a cross-sectional view of the partially completed FeRAM of FIG. 6 after defining the first protective layer, the first electrode, the ferroelectric dielectric layer, the second electrode and the second protective layer to form a completed ferroelectric capacitor; and

FIG. 8 illustrates an exemplary cross-sectional view of a conventional integrated circuit (IC) incorporating a ferroelectric capacitor constructed according to the principles of the present invention.

### DETAILED DESCRIPTION

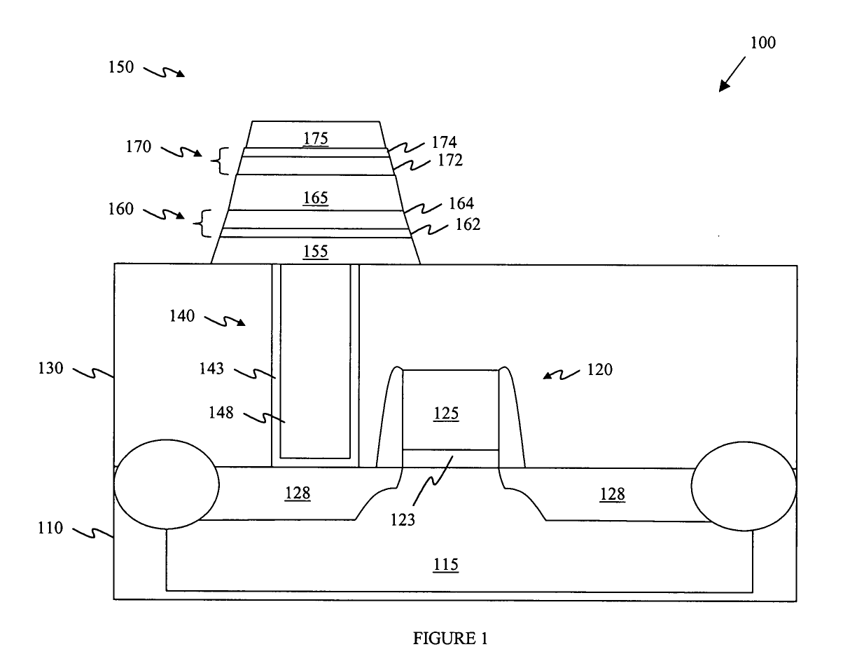

Referring initially to FIG. 1, illustrated is a cross-sectional view of one embodiment of a ferroelectric random access memory (FeRAM) device 100 constructed according to the principles of the present invention. In the embodiment illustrated in FIG. 1, the FeRAM 100 includes a substrate 110. Located within the substrate 110 in the embodiment of FIG. 1 is a well region 115. Additionally located over the substrate 110 and well region 115 is a transistor 120.

The transistor 120 illustrated in FIG. 1 includes a gate oxide 123 located over the substrate 110, as well as a gate electrode 125 located over the gate oxide 123. Flanking both sides of the gate electrode 125 and gate oxide 123 of the transistor 120 may be gate sidewall spacers. The transistor 120 illustrated in FIG. 1 further includes conventional source/drain regions 128 located within the substrate 110. The source/drain regions 128, as is common, may each include a lightly doped extension implant as well as a higher doped source/drain implant.

Located over the transistor 120 is a dielectric layer 130. The dielectric layer 130 may be any insulative material known for use in a semiconductor device, however, in the particular embodiment illustrated in FIG. 1 the dielectric layer 130 is an interlevel dielectric layer. Located within the dielectric layer 130 is an interconnect 140. The interconnect 140, as is common in the semiconductor art, includes a barrier layer 143 and a conductive plug 148. In the particular embodiment of FIG. 1 the conductive plug 148 comprises tungsten and the barrier layer 143 comprises a Ti/TiN stack. Nonetheless, other materials could be used. The interconnect 140 optimally contacts the drain region of the source/drain regions 128.

Advantageously located over the transistor 120 and contacting the interconnect 140 is a ferroelectric capacitor 150. The ferroelectric capacitor 150 in the embodiment of FIG. 1 includes a first protective layer 155, and a first electrode 160 located over the first protective layer 155. In the embodiment of FIG. 1 the first electrode 160 includes a first electrode layer 162 and a first oxide electrode template 164. The first electrode layer 162 may comprise a number of different materials while staying within the scope of the present invention, however, it has currently been observed that an iridium first electrode layer 162 is particularly beneficial. Other metals, including noble metals, could be used.

The first oxide electrode template 164, which is unique to the present invention, advantageously comprises a material having a substantially similar crystal structure as the ferroelectric dielectric layer 165 located thereover. The term substantially similar crystal structure, as used throughout this document, means the matching of the oxygen octahedron in the crystal structure of the ferroelectric material and the proposed perovskite or distorted perovskite electrode materials. The cations such as Pb and (Ti or Zr) in the case of PZT ferroelectric material are simply to be replaced by Sr and Ir for example in the case of SrIrO₃ respectively. One can imagine building blocks of oxygen octahedral and then after a certain thickness instead of inserting Sr and Ir ions in the open spaces, one starts inserting Pb and (Zr or Ti) ions respectively. Contrast this to a situation where one has to crystallize the oxygen octahedron on a metal surface such as Pt or Ir. In this case, the oxygen octahedron will need a lot more energy and therefore temperature to form due to lack of a preferred chemical ambient, i.e., oxygen. The first oxide electrode template 164 may have, among others, a thickness that ranges from about 20 nm to about 100 nm. Additionally, the first oxide electrode template 164 may advantageously have a resistivity of less than about 400 micro-ohms/cm.

The first oxide electrode template 164 in an exemplary embodiment comprises a perovskite material or a distorted perovskite material. For instance, the first oxide electrode template 164 may comprise SrIrO₃ or SrRuO₃ in various different embodiments. Similarly, the first oxide electrode template 164 may comprise BaPbO₃, PbIrO₃, PbRuO₃, BiRuO₃, BiIrO₃, (La,Sr)CoO₃, CaRuO₃, BaPbO₃, etc., while staying within the scope of the present invention. One of the keys to the first oxide electrode template 164 is that it has a crystalline structure more similar to the crystalline structure of the ferroelectric dielectric layer 165 than the traditional metal electrodes.

As indicated above, located over the first oxide electrode template 164 is a ferroelectric dielectric layer 165. The ferroelectric dielectric layer 165 in an advantageous embodiment comprises a perovskite material, such as lead zirconate titanate (PZT), strontium bismuth tantalate (SBT) or other similar materials. Located over the ferroelectric dielectric layer 165 in the embodiment of FIG. 1 is a second electrode 170. The second electrode 170, similar to the first electrode 160, may comprise more than one layer. For instance, the second electrode 170 of FIG. 1 includes a second oxide electrode template 172 and a second electrode layer 174. The second oxide electrode template 172, if used, is believed to have a different purpose than the first oxide electrode template 164. Namely, the second oxide electrode template 172 has little, if any, affect on the formation of the ferroelectric dielectric layer 165. Nevertheless, the second oxide electrode template 172 provides symmetry to the ferroelectric capacitor 150, which is known to increase the reliability of the FeRAM 100.

Additionally located over the second electrode 170 may be a second protective layer 175. It should be noted that other layers may or may not comprise the ferroelectric capacitor 150. Similarly, a ferroelectric capacitor 150 manufactured in accordance with the present invention may or may not have all the layers depicted in FIG. 1. Additionally, diffusion barrier layers (not shown) may be blanket deposited over the entire surface of the ferroelectric capacitor 150.

Unique to the present invention, the oxide electrode template 164 allows the ferroelectric dielectric layer 165 to be formed using less energy. As mentioned above, the oxide electrode template 164 has a more similar crystalline structure to the ferroelectric dielectric layer 165 than the first electrode layer 162. Accordingly, much less energy is required to crystallize the ferroelectric dielectric layer 165 on the first oxide electrode template 164 than the first electrode layer 162. As less energy is required, the temperature required to form the ferroelectric dielectric layer 165 may be reduced. For instance, it is believed that the temperature used to form the ferroelectric capacitor 150, and more specifically the ferroelectric dielectric layer 165 is reduced to less than about 500° C.

As the industry scales toward smaller feature sizes in next generation devices, smaller thermal budgets are required. This is specifically the case when using nickel silicides in place of cobalt silicides in the transistor 120. Accordingly, the aforementioned reduction in temperature allows the integration of nickel silicides into the FeRAM 100. As those skilled in the art are aware, the high temperatures previously used to form the ferroelectric dielectric layer 165 cause the resistance of nickel silicide layers to substantially increase.

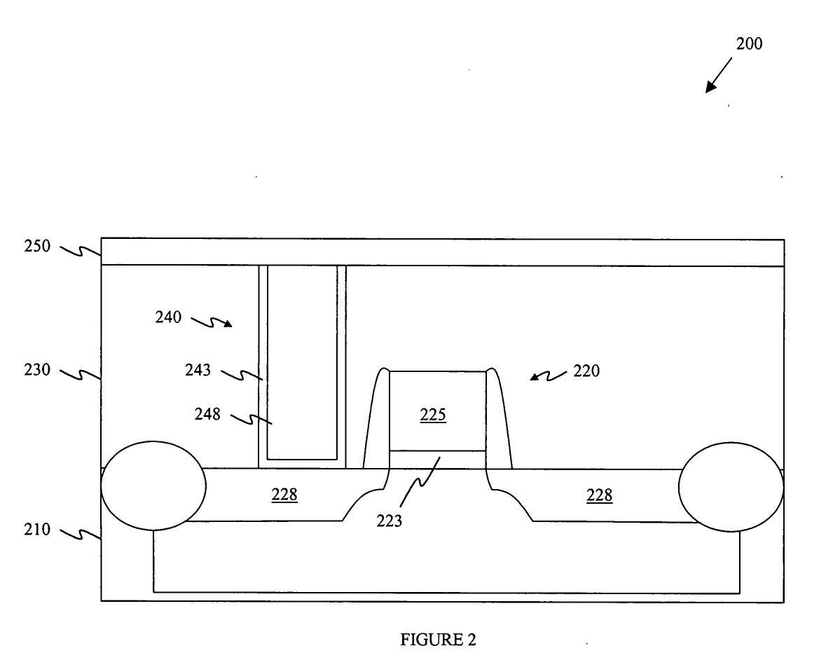

Turning now to FIGS. 2-7, illustrated are cross-sectional views of detailed manufacturing steps instructing how one might, in an advantageous embodiment, manufacture a FeRAM similar to the FeRAM 100 depicted in FIG. 1. FIG. 2 illustrates a cross-sectional view of a partially completed FeRAM 200. The partially completed FeRAM 200 of FIG. 2 includes a substrate 210. The substrate 210 may, in an exemplary embodiment, be any layer located in the partially completed FeRAM 200, including a wafer itself or a layer located above the wafer (e.g., epitaxial layer). In the embodiment illustrated in FIG. 2, the substrate 210 is a p-type semiconductor substrate; however, one skilled in the art understands that the substrate 210 could be an n-type substrate without departing from the scope of the present invention.

Located over the substrate 210 is a conventional transistor 220. Basically, the transistor 220 includes a gate dielectric 223 (preferably comprised of silicon dioxide, an oxynitride, a silicon nitride, BST, PZT, a silicate, any other high-k material, or any combination or stack thereof), a gate electrode 225 (preferably comprised of polycrystalline silicon doped either p-type or n-type with a silicide formed on top or a metal such as titanium, tungsten, TiN, tantalum, TaN), and side wall insulators (preferably comprised of an oxide, a nitride, an oxynitride, or a combination or stack thereof). In general the generic terms oxide, nitride and oxynitride refer to silicon oxide, silicon nitride and silicon oxy-nitride. The term “oxide” may, in general, include doped oxides as well as boron and/or phosphorous doped silicon oxide. Source/drain regions 228 are preferably implanted using conventional dopants and processing conditions. Lightly doped drain extensions as well as pocket implants may also be utilized. In addition, the source/drain regions 228 may be silicided (preferably with titanium, cobalt, nickel, tungsten or other conventional silicide material).

A dielectric layer 230 is formed over the entire substrate 210 and over the transistor 220. The dielectric layer 230 is, preferably, comprised of an oxide, FSG, PSG, BPSG, PETEOS, HDP oxide, a silicon nitride, silicon oxynitride, silicon carbide, silicon carbo-oxy-nitride, a low dielectric constant material (preferably SiLK, porous SiLK, Teflon, low-K polymer (possibly porous), aerogel, xerogel, BLACK DIAMOND, HSQ, or any other porous glass material), or a combination or stack thereof. Other known materials could, nonetheless, be used.

Located within the dielectric layer 230 is an interconnect 240. To form the interconnect 240 the dielectric layer 230 is patterned and etched so as to form an opening for contact to the substrate 210. This opening is filled with one or more conductive materials, such as a conductive plug 248 (preferably comprised of a metal such as tungsten, molybdenum, titanium, titanium nitride, tantalum nitride, metal silicide such as Ti, Ni or Co, copper or doped polysilicon). A barrier layer 243 may or may not be formed between the conductive plug 248 and dielectric layer 230. While the barrier layer 243 may comprise a multitude of different materials, the barrier layer 243 of FIG. 1 is, preferably, comprised of Ti, TiN, TaSiN, Ta, TaN, TiSiN, a stack thereof, or any other conventional barrier material. Preferably, the interconnect 240 will be formed so as to land on the silicided regions of the source/drain regions 228.

optionally located over the dielectric layer 230 is a first protective layer 250. The first protective layer 250 may or may not be formed depending on whether the interconnect 240 needs to be protected during subsequent processing of the capacitor dielectric. If formed, the first protective layer 250 is, preferably, comprised of TiAlN or other possible barriers (some of which have a slow oxidation rate compared to TiN) which include: TiAl, TaSiN, TiSiN, TiN, TaN, HfN, ZrN, HfAlN, CrN, TaAlN, CrAlN, or any other conductive material. The thickness of this layer is, preferably, on the order of 60 nm, however, it may range from about 50 nm to about 100 nm, or outside that range, without departing from the scope of the present invention. In the future, scaling the via size will allow scaling of the first protective layer 250 as well.

The preferred deposition technique for the first protective layer 250 is reactive sputter deposition using Ar+N₂ or Ar+NH₃. It should be noted that Ar is the standard inert gas used for sputter deposition or physical etching based on cost and performance. It is possible to use other inert gases instead of Ar for these applications throughout the process described in this document. Other deposition techniques that might be used include chemical vapor deposition (CVD), plasma enhanced CVD (PECVD), or atomic layer deposition (ALD). CVD of nitrides actually results in carbo-oxy-nitrides, especially when metalorganic precursors are used. For the preferred tungsten contact it is desirable to deposit a bilayer diffusion barrier. First, CVD TiN (40 nm is preferred) is deposited followed by PVD TiAlN (30 nm preferred). Even more preferred would be CVD or PECVD deposition of TiAlN (about 60 nm). The preferred proportion of aluminum in TiAlN is around 30-60% Al and 40-50% is more preferred in order to have improved oxidation resistance. A better first protective layer 250 (such as the one of an embodiment of the instant invention) will, in general, allow the oxygen stable bottom electrode material to be thinner or a higher process temperature to be used.

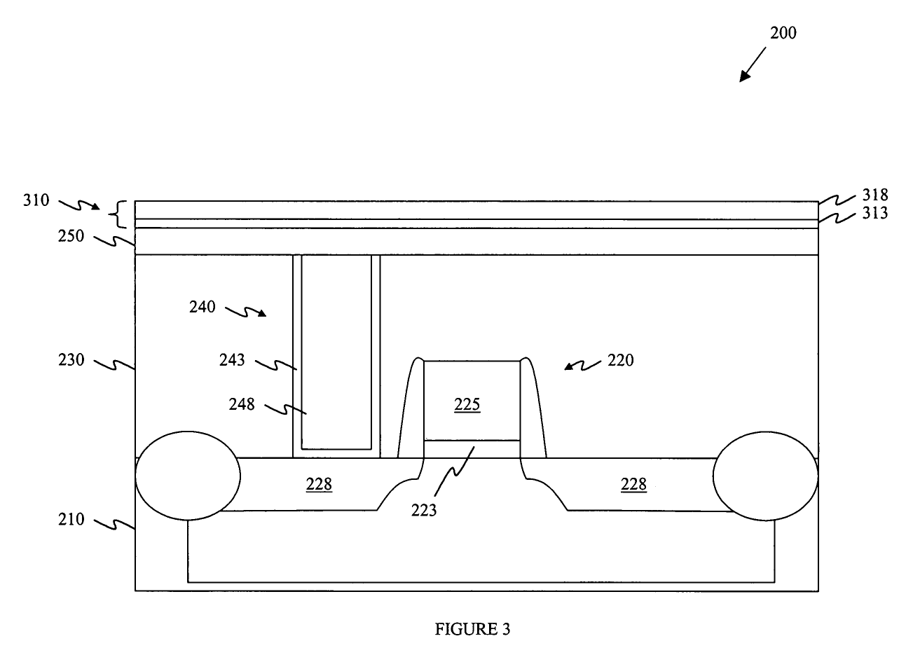

Turning now to FIG. 3, illustrated is a cross-sectional view of the partially completed FeRAM 200 of FIG. 2 after forming a first electrode 310 over the optional first protective layer 250. The first electrode 310 may be either formed on the first protective layer 250 or directly on the dielectric layer 230 so as to make electrical connection with the underlying contact structure.

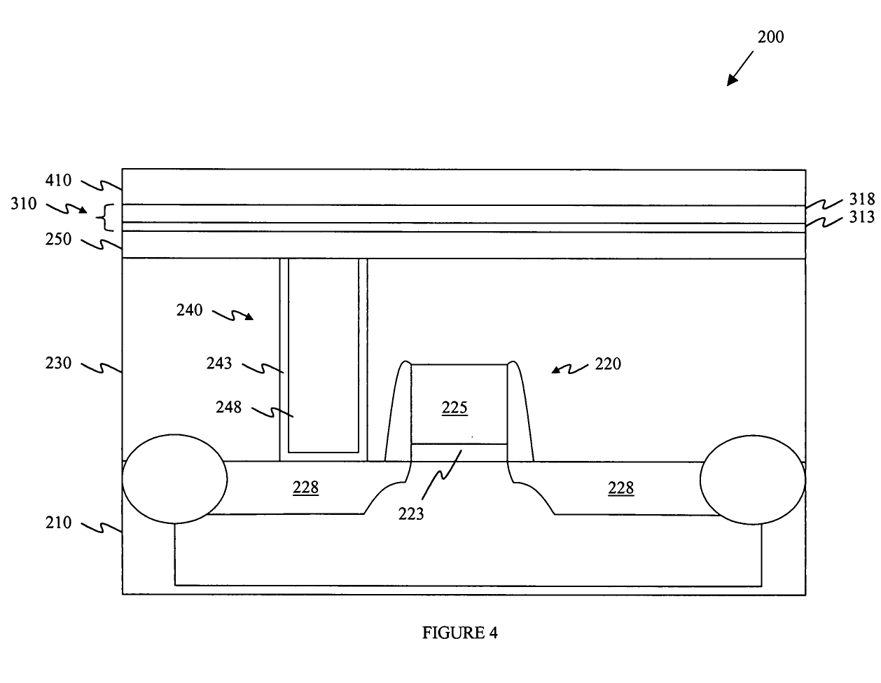

The first electrode 310 in the embodiment of FIG. 3 includes a first electrode layer 313 and a first oxide electrode template 318. In the embodiments of the present invention the first oxide electrode template 318 is located between the first electrode layer 313 and a subsequently formed ferroelectric dielectric layer 410 (FIG. 4). Preferably, the first electrode layer 313 is sputter deposited to a thickness ranging from about 20 nm to about 100 nm. Additionally, it is preferable for the first electrode layer 313 to be stable in oxygen, and comprise a noble metal such as Ir, Ru, or Pd. It is believed that the first electrode layer 313 substantially prevents oxygen introduced during the manufacture of the first oxide electrode template 318 from negatively affecting the interconnect 240, and therefore is often used.

Uniquely formed over the first electrode layer 313 is the first oxide electrode template 318. The first oxide electrode template 318, in contrast to the first electrode layer 313, comprises a perovskite material. For instance, the first oxide electrode template 318 may comprise SrIrO₃ and SrRuO₃, as well as BaPbO₃, PbIrO₃, PbRuO₃, BiRuO₃, BiIrO₃, (La,Sr)CoO₃₁ CaRuO₃, and BaPbO₃ while staying within the scope of the present invention. As previously discussed, it is important that the first oxide electrode template 318 comprise a material having a substantially similar crystal structure to the subsequently formed ferroelectric dielectric layer 410 (FIG. 4).

The first oxide electrode template 318 may be formed to a thickness ranging from about 20 nm to about 100 nm. Additionally, the first oxide electrode template 318 may be manufactured using a CVD process and having a resistivity of less than about 400 micro-ohms/cm. The preferred deposition technique for the first oxide electrode template 318 is reactive sputter deposition using Ar+O₂ or Ar+N₂O using a ceramic target of the material or simultaneous deposition from targets of individual components of the material. It should be noted that Ar is the standard inert gas used for sputter deposition or physical etching based on cost and performance. It is possible to use other inert gases instead of Ar for these applications throughout the process described in this document. Other deposition techniques that might be used include chemical vapor deposition (CVD), plasma enhanced CVD (PECVD), Atomic Layer Deposition (ALD), or Metal Organic Chemical Vapor Deposition (MOCVD). The preferred composition would be stoichiometric with respect to the individual components.

Turning now to FIG. 4, illustrated is a cross-sectional view of the partially completed FeRAM 200 of FIG. 3 after forming a ferroelectric dielectric layer 410 over the first electrode 310, and more particularly on the first oxide electrode template 318. Preferably, the ferroelectric dielectric layer 410 has a thickness ranging from about 150 nm to about 20 nm. The ferroelectric dielectric layer 410 comprises a ferroelectric material, such as lead zirconate titanate (PZT); doped PZT with donors (Nb, La, Ta), acceptors (Mn, Co, Fe, Ni, Al), and/or both; PZT doped and alloyed with SrTiO₃, BaTiO₃ or CaTiO₃; strontium bismuth tantalate (SBT) and other layered perovskites such as strontium bismuth niobate tantalate (SBNT); or bismuth titanate; BaTiO₃; PbTiO₃; or Bi₂TiO₃.

PZT is the most preferable choice for the ferroelectric dielectric layer 410 because it has the highest polarization and the lowest processing temperature of the aforementioned materials. In addition, the preferred Zr/Ti composition is around 20/80, respectively, in order to obtain good ferroelectric switching properties (large switched polarization and relatively square-looking hysterisis loops). Alternatively Zr/Ti compositions of approximately 65/35 may be preferred to maximize uniformity in capacitor properties. The donor dopant may improve the reliability of the PZT by helping to control the point defect concentrations.

The preferred deposition technique for the ferroelectric dielectric layer 410 is metal organic chemical vapor deposition (MOCVD). MOCVD is preferred especially for thin films (i.e., films less than 100 nm thick). Thin PZT is extremely advantageous in making integration simpler (less material to etch), cheaper (less material to deposit therefore less precursor) and allows lower voltage operation (lower coercive voltage for roughly the same coercive electric field). The ferroelectric dielectric layer 410 can be deposited in either a single crystalline/poly-crystalline state or it can be deposited in an amorphous phase at low temperatures and then crystallized using a post-deposition anneal. This is commonly done for Bi ferroelectric films. The post deposition crystallization anneal can be performed immediately after deposition or after later process steps such as electrode deposition or post capacitor etch anneal. The preferred MOCVD PZT approach results in a poly-crystalline film completely formed using temperatures of about 500° C. or less, and more preferably between about 400° C. and about 450° C.

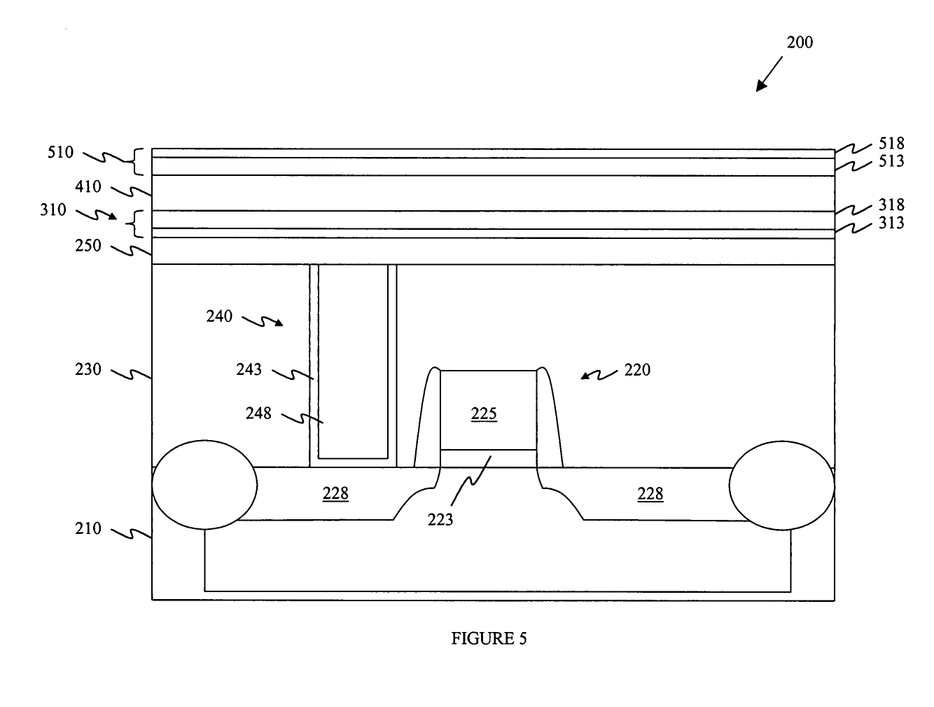

Turning now to FIG. 5, illustrated is a cross-sectional view of the partially completed FeRAM 200 of FIG. 4 after forming a second electrode 510 over the ferroelectric dielectric layer 410. In this embodiment of the instant invention, the second electrode 510 is illustrated as a second oxide electrode template 513 and a second electrode layer 518. However, the second electrode 510 can be implemented in just one layer. Preferably, the second oxide electrode template 513 comprises a perovskite material, similar to the material used to form the first oxide electrode template 318, and has a thickness ranging from about 20 nm to about 100 nm. Preferably, the second electrode layer 518 comprises a noble metal such as iridium, and has a thickness ranging from about 20 nm to about 100 nm. The second oxide electrode template 513 and the second electrode layer 518 may be formed using similar techniques as used to form the first oxide electrode template 318 and first electrode layer 313, respectively.

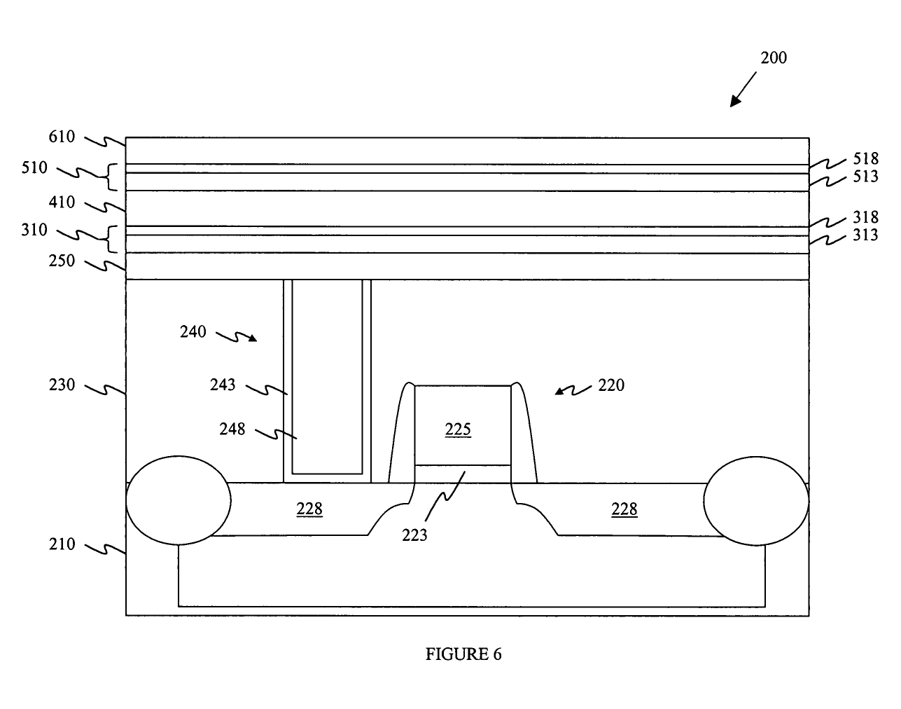

Turning now to FIG. 6, illustrated is a cross-sectional view of the partially completed FeRAM 200 of FIG. 5 after forming a second protective layer 610 over the second electrode 510. Preferably, the second protective layer 610 comprises a material which is thick enough so as to retain its integrity during a subsequent etch process. The second protective layer 610 is, preferably, around about 50 nm to about 500 nm thick (more preferably around about 100 nm to about 300 nm thick—most preferably around about 200 nm thick) and comprises TiAlN, TiN, Ti, TiO₂, Al, AlOₓ, AlN, TiAl, TiAlOₓ, Ta, TaOₓ, TaN, Cr, CrN, CrOₓ, Zr, ZrOₓ, ZrN, Hf, HfN, HfOₓ, silicon oxide, low-k dielectric, or any stack or combination thereof. An example of a second protective layer 610 is 300 nm of PECVD deposited SiO₂ on 50 nm of sputter deposited TiAlN or TiN. The second protective layer 610 thickness is controlled by the etch process and the relative etch rates of the various materials, the thicknesses of the etched layers, the amount of overetch required, and the desired remaining second protective layer 610 thickness after etching all of the layers.

The second protective layer 610 may or may not be removed after the etching of the capacitor stack. If the second protective layer 610 is not removed, then it is preferable to form it of a conductive material. However, a non-conductive or semiconductive material may be used, but the interconnection to the second electrode 510 of the capacitor should preferably be formed through this layer so as to make direct connection to the second electrode 510.

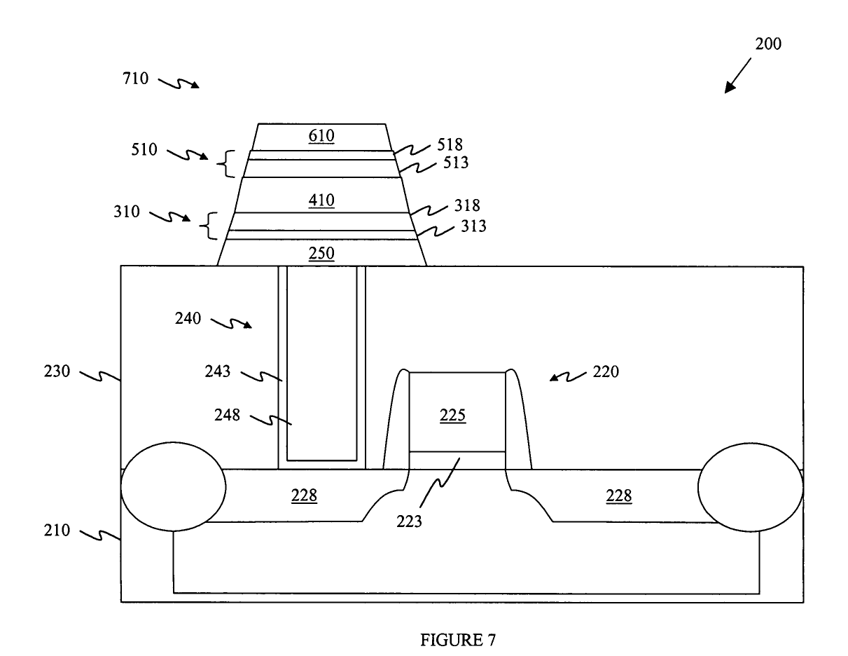

Turning now to FIG. 7, illustrated is a cross-sectional view of the partially completed FeRAM 200 of FIG. 6 after defining the first protective layer 250, the first electrode 310, the ferroelectric dielectric layer 410, the second electrode 510 and the second protective layer 610 to form a completed ferroelectric capacitor 710. It is preferred to perform the pattern and etch process for the completed ferroelectric capacitor 710 with only one lithography step. This is not only cheaper, but also allows the cell size to be smaller by eliminating misalignment tolerances which are necessary if more than one lithography step is used.

The etch process is a dirty process and hence it is likely that the etch tool and the frontside, edge and backside of the wafers will have FeRAM contamination or have etch residues with FeRAM contamination. It is, therefore, often necessary to clean the frontside of the wafer and chemically remove etch residues and possibly remove a thin layer of damaged PZT. This post-capacitor-etch wet-clean may, with some etch conditions and chemistries, be as simple as a deionized water (DI water or DIW) clean (tank soak with or without megasonic followed by a spin rinse dry) or the tank etch might be acid-based in order to improve the clean or remove more damage.

The sidewalls of the completed ferroelectric capacitor 710 are, preferably, fairly steep. A sidewall diffusion barrier is, preferably, formed on the completed ferroelectric capacitor 710 prior to the formation of another interlevel dielectric thereover. The sidewall diffusion barrier is important because it allows for the misalignment of the interconnect without shorting the capacitor, it protects the capacitor from the diffusion of most substances into the capacitor, and it protects the rest of the structures from the out-diffusion of substances from the capacitor. The sidewall diffusion barrier often comprises two layers, but the sidewall diffusion barrier may be comprised of more or fewer layers and stay within the scope of the present invention. Preferably, the first layer is around 30 nm thick and is comprised of AlOₓ, Ta₂O₅, AlN, TiO₂, ZrO₂, HfO₂, or any stack or combination thereof; and the second layer is around 30 nm thick and is comprised of silicon nitride, AlN, or any stack or combination thereof. The preferred process for depositing these layers is MOCVD under conditions with minimal free hydrogen (e.g., enough oxygen such that H₂O is formed rather than H₂). It is also possible to use a plasma enhanced CVD or MOCVD process. Alternatively reactive sputter deposition can be used with either Ar+O₂ (for oxides), Ar+N₂ (for nitrides) or Ar+O₂+N₂ (for oxy-nitrides). For the preferred embodiment listed here, the first layer is used as a Pb and H diffusion barrier while the second layer is used as a contact etch stop. Subsequent to the formation of the first and second diffusion barrier layers the manufacturing process would continue resulting in a device similar to the FeRAM 100 illustrated in FIG. 1.

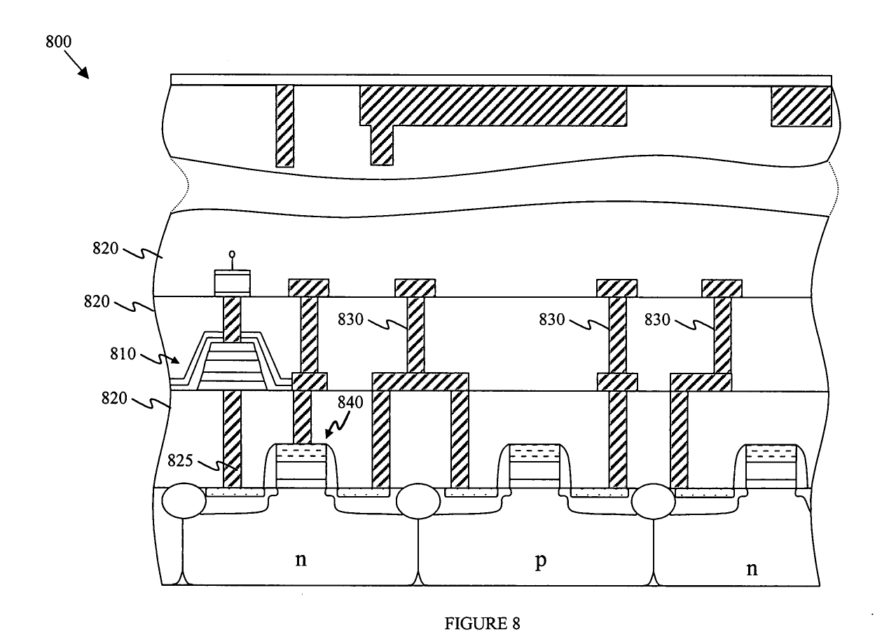

Referring finally to FIG. 8, illustrated is an exemplary cross-sectional view of a conventional integrated circuit (IC) 800 incorporating a ferroelectric capacitor 810 constructed according to the principles of the present invention. The IC 800 may include devices, such as transistors used to form CMOS devices, BiCMOS devices, Bipolar devices, as well as capacitors or other types of devices. The IC 800 may further include passive devices, such as inductors or resistors, or it may also include optical devices or optoelectronic devices. Those skilled in the art are familiar with these various types of devices and their manufacture. In the particular embodiment illustrated in FIG. 8, the IC 800 includes the ferroelectric capacitor 810 having dielectric layers 820 located thereunder and thereover. Additionally, interconnect structures 830 are located within the dielectric layers 820 to interconnect various devices. Specifically, interconnect structure 825 connects the ferroelectric capacitor 810 to source/drain regions of the transistor 840, thus, forming the operational integrated circuit 800.

Although the present invention has been described in detail, those skilled in the art should understand that they can make various changes, substitutions and alterations herein without departing from the spirit and scope of the invention in its broadest form.

1. A ferroelectric capacitor, comprising:
a first electrode layer located over a substrate, wherein the first electrode layer includes iridium;
an oxide electrode template located over the first electrode layer;
a ferroelectric dielectric layer located over the oxide electrode template; and
a second electrode layer located over the ferroelectric dielectric layer.

2. The ferroelectric capacitor as recited in claim 1 wherein the oxide electrode template forms a portion of a first electrode.

3. The ferroelectric capacitor as recited in claim 1 wherein the oxide electrode template comprises a perovskite material.

4. The ferroelectric capacitor as recited in claim 1 wherein the oxide electrode template comprises a distorted perovskite material.

5. The ferroelectric capacitor as recited in claim 1 wherein the oxide electrode template is selected from the group consisting of SrIrO₃ and SrRuO₃.

6. The ferroelectric capacitor as recited in claim 1 wherein the oxide electrode template is selected from the group consisting of BaPbO₃, PbIrO₃, PbRuO₃, BiRuO₃, BiIrO₃, (La,Sr)CoO₃, CaRuO₃, and BaPbO₃.

7. The ferroelectric capacitor as recited in claim 1 wherein the oxide electrode template has a thickness ranging from about 20 nm to about 100 nm.

8. The ferroelectric capacitor as recited in claim 1 wherein the oxide electrode template has a resistivity less than about 400 micro-ohms/cm.

9. The ferroelectric capacitor as recited in claim 1 wherein the oxide electrode template and the ferroelectric dielectric layer have substantially similar crystal structures.

10. The ferroelectric capacitor as recited in claim 1 wherein the oxide electrode template is a first oxide electrode template and further including a second oxide electrode template located between the ferroelectric dielectric layer and the second electrode layer.

11. A method for manufacturing a ferroelectric capacitor, comprising:
forming a first electrode layer over a substrate;
forming an oxide electrode template over the first electrode layer;
forming a ferroelectric dielectric layer over the oxide electrode template; and
forming a second electrode layer over the ferroelectric dielectric layer, wherein the ferroelectric capacitor is formed only using temperatures of about 500° C. or less.

12. The method as recited in claim 11 wherein forming an oxide electrode template includes forming an oxide electrode template comprising a perovskite material.

13. The method as recited in claim 11 wherein forming an oxide electrode template includes forming an oxide electrode template comprising a distorted perovskite material.

14. The method as recited in claim 11 wherein forming an oxide electrode template includes forming an oxide electrode template comprising a material selected from the group consisting of SrIrO₃ and SrRuO₃.

15. The method as recited in claim 11 wherein forming an oxide electrode template includes forming an oxide electrode template comprising a material selected from the group consisting of BaPbO₃, PbIrO₃, PbRuO₃, BiRuO₃, BiIrO₃, (La,Sr)CoO₃, CaRuO₃, and BaPbO₃.

16. The method as recited in claim 11 wherein forming an oxide electrode template includes forming an oxide electrode template having a thickness ranging from about 20 nm to about 100 nm.

17. The method as recited in claim 11 wherein forming an oxide electrode template includes forming an oxide electrode template having a resistivity less than about 400 micro-ohms/cm.

18. The method as recited in claim 11 wherein forming an oxide electrode template and forming a ferroelectric dielectric layer includes forming an oxide electrode template and forming a ferroelectric dielectric layer having substantially similar crystal structures.

19. The method as recited in claim 11 wherein forming an oxide electrode template includes forming a first oxide electrode template and further including forming a second oxide electrode template between the ferroelectric dielectric layer and the second electrode layer.

20. The method as recited in claim 11 wherein the first electrode layer is an iridium electrode layer.

21. A ferroelectric random access memory (FeRAM) device, comprising:
a transistor having source/drain regions located over a semiconductor substrate;
an interlevel dielectric layer located over the transistor, the interlevel dielectric layer having a conductive plug therein contacting at least one of the source/drain regions; and
a ferroelectric capacitor located over the interlevel dielectric layer and contacting the conductive plug, including;
a first electrode layer located over the interlevel dielectric layer, wherein the first electrode layer includes iridium;
an oxide electrode template located over the first electrode layer;
a ferroelectric dielectric layer located over the oxide electrode template; and
a second electrode layer located over the ferroelectric dielectric layer.

22. The ferroelectric random access memory (FeRAM) device as recited in claim 21 wherein at least a portion of the transistor includes a nickel silicide.
